(19) United States
(12) Patent Application Publication
(10) Pub. No.: US 2018/0174987 A1
(43) Pub. Date: Jun. 21, 2018

(54) SEMICONDUCTOR DEVICE

(71) Applicant: FUJI ELECTRIC CO., LTD., Kanagawa (JP)

(72) Inventors: Mikiya CHOUNABAYASHI, Matsumoto-city (JP); Ryohei MAKINO, Hachioji-city (JP); Hayato NAKANO, Matsumoto-city (JP)

(21) Appl. No.: 15/794,000

(22) Filed: Oct. 26, 2017

(30) Foreign Application Priority Data
Nov. 2, 2016 (JP) 2016-215650

(51) Int. Cl. H01L 23/64; H01L 23/482; H01L 23/00

(52) U.S. Cl. CPC H01L 23/647; H01L 23/4827; H01L 2924/13091; H01L 2924/30107; H01L 2924/13055; H01L 24/14

(57) ABSTRACT

A semiconductor device is provided that includes a semiconductor chip having a main terminal and a control terminal, a main connection pin electrically connected to the main terminal, and a control connection pin electrically connected to the control terminal and having an electrical resistance higher than that of the main connection pin. The control connection pin may be a control internal connection pin or a control external connection pin. The control connection pin may include material having an electrical resistivity higher than that of material of the main connection pin. The control connection pin may have a shape different from that of the main connection pin.

The contents of the following Japanese patent application(s) are incorporated herein by reference:
NO. 2016-215650 filed on Nov. 2, 2016.

### BACKGROUND

### 1. Technical Field

The present invention relates to semiconductor devices.

### 2. Related Art

Conventionally, a semiconductor module has been known that is equipped with a semiconductor chip such as an IGBT (insulated gate type bipolar transistor) (see Patent Document 1, for example). A connection pin is electrically connected to a terminal of the semiconductor chip. The connection pin is, for example, directly connected to the terminal of the semiconductor chip, and connects the semiconductor chip and a printed substrate.
Patent Document 1: Japanese Patent Application Publication No. 2012-119618

In order to increase power capacity, a plurality of semiconductor chips are arranged in parallel in a semiconductor module, or a plurality of semiconductor modules are arranged in parallel in some cases. If the semiconductor chips or the semiconductor modules are provided in parallel, electrical oscillations are in some cases generated between the semiconductor chips or the semiconductor modules due to inductance of gate wiring electrically connected to a gate terminal of the semiconductor chips and due to gate capacitance or the like of the semiconductor element such as an IGBT. It is considered to provide a resistor on the gate wiring in order to suppress the electrical oscillations.

Also, even if the semiconductor chips or the semiconductor modules are not arranged in parallel, a resistor is provided in some cases on the gate wiring for protection of the semiconductor element or for adjustment of the electrical characteristics. However, if a chip resistor or the like is provided on the gate wiring, the wiring pattern becomes complicated and also the cost increases.

### SUMMARY

A first aspect of the present invention provides a semiconductor device including a semiconductor chip that has a main terminal and a control terminal. The semiconductor device may include a main connection pin electrically connected to the main terminal. The semiconductor device may include a control connection pin electrically connected to the control terminal and having an electrical resistance higher than that of the main connection pin.

The control connection pin may include material having an electrical resistivity higher than that of material of the main connection pin. The control connection pin may include at least one of tungsten and titanium.

The control connection pin may have a portion a diameter of which is smaller than a diameter of the main connection pin. The control connection pin may have a current path longer than that of the main connection pin.

The control connection pin may have a first portion and a second portion that is connected to an end of the first portion and formed of material having an electrical resistivity higher than that of material of the first portion. The first portion may be formed of copper, and the second portion may include at least one of tungsten and titanium.

The semiconductor device may include a package portion that accommodates the semiconductor chip, and a wiring substrate that is accommodated in the package portion and arranged to face the semiconductor chip. The control connection pin may be a control internal connection pin that electrically connects, inside the package portion, the control terminal of the semiconductor chip and the wiring substrate. The semiconductor device may include a plurality of the semiconductor chips in parallel, and the control internal connection pin may be provided to each semiconductor chip.

The semiconductor device may further include a package portion that accommodates the semiconductor chip, and the control connection pin may be a control external connection pin at least part of which is exposed to outside of the package portion. The semiconductor device may include a plurality of the semiconductor chips in parallel. Two or more of the semiconductor chips may be electrically connected to the one control external connection pin.

The semiconductor device may include a plurality of package portions in parallel. The control external connection pin may be provided in each of the package portion.

The semiconductor device may include a wiring substrate accommodated in the package portion and arranged to face the semiconductor chip. The semiconductor device may include a main internal connection pin that electrically connects, inside the package portion, the main terminal of the semiconductor chip and the wiring substrate. The semiconductor device may include a control internal connection pin that electrically connects, inside the package portion, the control terminal of the semiconductor chip and the wiring substrate and that has an electrical resistance higher than that of the main internal connection pin. The control internal connection pin may have an electrical resistance higher than that of the control external connection pin.

The summary clause does not necessarily describe all necessary features of the embodiments of the present invention. The present invention may also be a sub-combination of the features described above.

### BRIEF DESCRIPTION OF THE DRAWINGS

FIG. 1 is a schematic view showing a cross section of a semiconductor module 100, which is an exemplary semiconductor device.

FIG. 2 is a schematic perspective view showing semiconductor chips 20, control internal connection pins 31, and main internal connection pins 32.

FIG. 3 is a diagram showing an exemplary semiconductor device 300.

FIG. 4 is a side view showing an exemplary shape of the control internal connection pin 31.

FIG. 5 is a perspective view showing another exemplary shape of the control internal connection pin 31.

FIG. 6 is a cross-sectional view showing another exemplary shape of the control internal connection pin 31.

FIG. 7 is a diagram showing another exemplary semiconductor device 300.

FIG. 8 is a diagram showing another exemplary semiconductor device 300.

FIG. 9 is a diagram showing another exemplary semiconductor device 300.

### DESCRIPTION OF EXEMPLARY EMBODIMENTS

Hereinafter, (some) embodiment(s) of the present invention will be described. The embodiment(s) do(es) not limit the invention according to the claims. Also, all the combinations of the features described in the embodiment(s) are not necessarily essential to means provided by aspects of the invention.

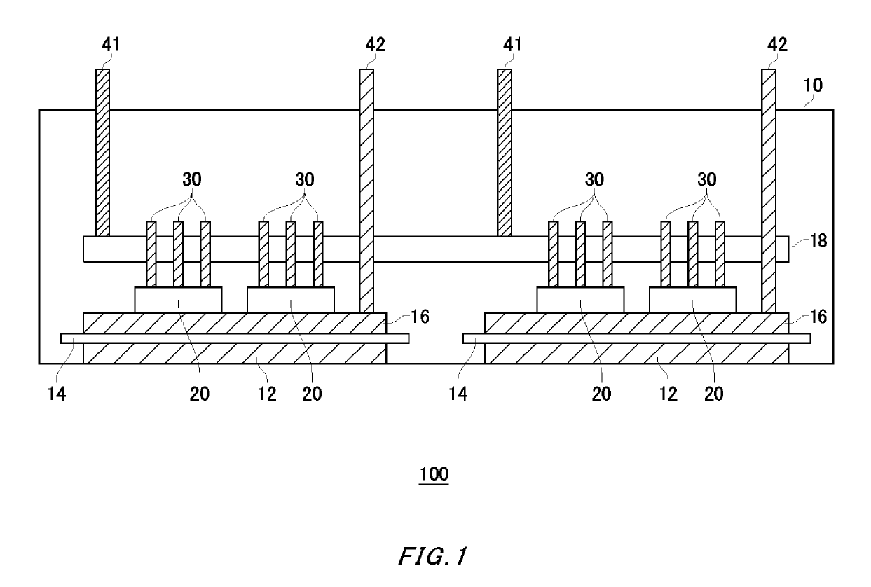

FIG. 1 is a schematic view showing a cross section of a semiconductor module 100, which is an exemplary semiconductor device. The semiconductor module 100 is a semiconductor module for power conversion, for example. The semiconductor module 100 can be used in an inverter device, an uninterruptible power supply device, a power conditioner, a vehicle such as a railway vehicle, a machine tool, an industrial robot, and the like. However, applications of the semiconductor module 100 are not limited to those above described.

The semiconductor module 100 is equipped with one or more semiconductor chips 20. The semiconductor module 100 shown in FIG. 1 is equipped with a plurality of semiconductor chips 20. The semiconductor module 100 may be equipped with an upper arm portion and a lower arm portion of an inverter circuit. A plurality of semiconductor chips 20 may be included in each arm portion.

The semiconductor chip 20 includes a power semiconductor switching element such as a MOSFET. Terms, ‘source’ and ‘drain,’ are herein used in some cases, but the semiconductor element included in the semiconductor chip 20 is not limited to a MOSFET. The semiconductor element may be a bipolar transistor such as an IGBT. In this case, terms, ‘source’ and ‘drain,’ can be appropriately replaced by terms, ‘emitter’ and ‘collector.’

The semiconductor element included in the semiconductor chip 20 may be formed of a silicon semiconductor or the like. It may also be formed of a chemical compound semiconductor of silicon carbide and gallium nitride or the like, the chemical compound semiconductor having a wide band gap. The semiconductor element may also be a SiC-MOSFET, a SiC-JFET, a GaN-HEMT, or the like.

Each semiconductor chip 20 is accommodated in a package portion 10 formed of insulating material such as resin. The package portion 10 is sealed such that the semiconductor chips 20 are not exposed.

The semiconductor chips 20 are arranged on a plate-shaped upper base portion 16 formed of conductive material such as copper. The upper base portion 16 may be electrically connected to any one of terminals of the respective semiconductor chips 20. The upper base portion 16 of the present example is connected to a main terminal of the semiconductor chip 20. The main terminal refers to, for example, a terminal connected to a source or a drain of a MOSFET. A main external connection pin 42 is connected to the upper base portion 16. An end of the main external connection pin 42, the end opposite to the upper base portion 16, is exposed to the outside of the package portion 10.

The upper base portion 16 is arranged above a plate-shaped lower base portion 12 with an insulating substrate 14 interposed therebetween. The upper base portion 16, the insulating substrate 14, and the lower base portion 12 are accommodated in the package portion 10. However, the lower surface of the lower base portion 12 may be exposed to the lower surface of the package portion 10 in order to improve heat release efficiency.

The semiconductor module 100 includes a wiring substrate 18 accommodated in the package portion 10 and arranged to face the semiconductor chip(s) 20. The wiring substrate 18 is a printed substrate, for example. In the wiring substrate 18, wiring for electrically connecting a circuit provided outside the semiconductor module 100 and the terminals of the semiconductor chips 20 is formed. Control external connection pin(s) 41 are connected to the wiring substrate 18 of the present example. The control external connection pin(s) 41 are connected to control terminals of the semiconductor chips 20 via the wiring substrate 18. The control terminal of the semiconductor chip 20 refers to a terminal connected to a gate in a MOSFET, for example. End(s) of the control external connection pin(s) 41, the end(s) opposite to the wiring substrate 18, are exposed to the outside of the package portion 10.

Note that FIG. 1 shows the control external connection pins 41 and the main external connection pins 42. However, the semiconductor module 100 may have more external connection pins. For example, the semiconductor module 100 may have the main external connection pins 42, which each have one end thereof connected to the wiring substrate 18 and the other end thereof exposed to the outside of the package portion 10. The main external connection pins 42 are each connected to a main terminal of the semiconductor chips 20 via the wiring substrate 18.

The semiconductor module 100 includes a plurality of internal connection pins 30 accommodated in the package portion 10. The internal connection pins 30 are provided between the semiconductor chips 20 and the wiring substrate 18 and electrically connect the terminals of the semiconductor chip 20 and the wiring in the wiring substrate 18. The plurality of internal connection pins 30 include a main internal connection pin connected to the main terminal of the semiconductor chip 20 and a control internal connection pin connected to the control terminal of the semiconductor chip 20.

The external and internal connection pins are each formed of conductive material, and at least one or some of them are formed to have a columnar shape. The connection pins may include crooked portions. They may include regions with different diameters.

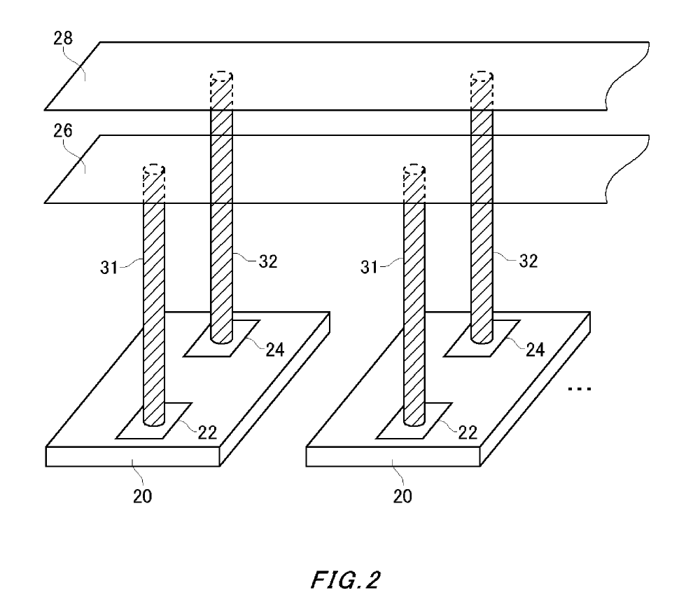

FIG. 2 is a schematic perspective view showing the semiconductor chips 20, the control internal connection pins 31, and the main internal connection pins 32. FIG. 2 shows one control internal connection pin 31 and one main internal connection pin 32 per semiconductor chip 20. However, a plurality of control internal connection pins 31 and a plurality of main internal connection pins 32 may be provided per semiconductor chip 20. Each semiconductor chip 20 has a control terminal 22 and a main terminal 24. The control terminal 22 and the main terminal 24 of the present example are electrode pads formed on the upper surface of the semiconductor chip 20 facing the wiring substrate 18.

The wiring substrate 18 shown in FIG. 1 has control wiring 26 and main wiring 28 shown in FIG. 2. Although the control wiring 26 and the main wiring 28 are formed of conductive material and on an insulating substrate, FIG. 2 omits the substrate. The control terminals 22 of the plurality of semiconductor chips 20 are electrically connected to the control wiring 26. The main terminals 24 of the plurality of semiconductor chips 20 are electrically connected to the main wiring 28.

Each control internal connection pins 31 is directly connected to the control terminal 22 of the semiconductor chip 20. One end of each control internal connection pin 31 is fixed to the control terminal 22 with solder or the like. The other end of each control internal connection pin 31 is fixed to the wiring substrate 18 with solder or the like, and is electrically connected to the control wiring 26.

Each main internal connection pin 32 is directly connected to the main terminal 24 of the semiconductor chip 20. One end of each main internal connection pin 32 is fixed to the main terminal 24 with solder or the like. The other end of each main internal connection pin 32 is fixed to the wiring substrate 18 with solder or the like and is electrically connected to the main wiring 28.

The control internal connection pin 31 of the present example has an electrical resistance higher than that of the main internal connection pin 32. For example, the control internal connection pin 31 includes material having an electrical resistivity higher than that of the material of the main internal connection pin 32. As a more specific example, the main internal connection pin 32 is formed of copper, and the control internal connection pin 31 includes at least one of tungsten and titanium. The control internal connection pin 31 may be formed of alloy including at least one of tungsten and titanium. It may be formed of only tungsten or titanium. Two or more conducting portions formed of different materials may be connected to the control internal connection pin 31. However, material of each connection pin is not limited to the above examples.

In a case where the electrical resistivity of the material of the control internal connection pin 31 is higher than the electrical resistivity of the material of the main internal connection pin 32, the shape and size of the control internal connection pin 31 and those of the main internal connection pins 32 may be the same. Note that the electrical resistance of the control internal connection pin 31 may be increased by making the control internal connection pin 31 and the main internal connection pin 32 different in shape, such as by making the control internal connection pin 31 thinner than the main internal connection pin 32. Also, the electrical resistance of the control internal connection pin 31 may be increased by making the control internal connection pin 31 and the main internal connection pin 32 different in both shape and material. For example, the electrical resistance of the main internal connection pin 32 is approximately 0Ω, and the electrical resistance of the control internal connection pin 31 is approximately 2Ω or more and 100Ω or less.

By increasing the electrical resistance of the control internal connection pin 31, the gate resistance of the semiconductor chip 20 can be set to a predetermined resistance value without adding an external resistor to the semiconductor chip 20. This can reduce the complexity of the wiring pattern in the wiring substrate 18 and also reduce the component cost. In particular, when the number of semiconductor chips 20 in parallel is added in order to increase the power capacity of the semiconductor module 100, and a resistor is externally mounted per semiconductor chip 20, the wiring in the wiring substrate 18 becomes complicated, and it becomes very difficult to secure areas enough to install the resistors.

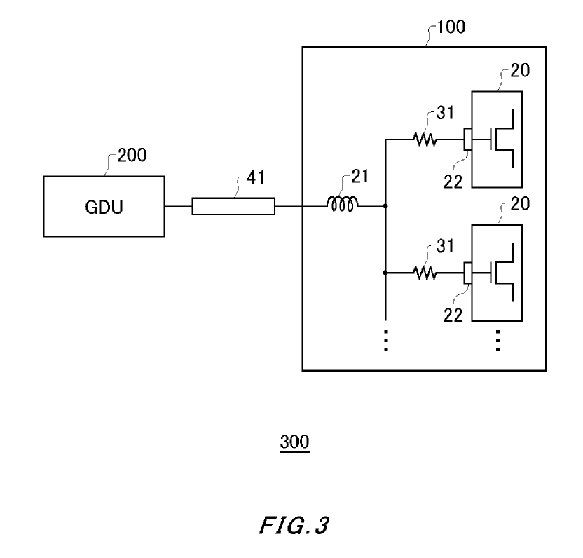

FIG. 3 is a diagram showing an exemplary semiconductor device 300. The semiconductor device 300 includes a gate driver unit 200 and the semiconductor module 100. The semiconductor module 100 is the same as the semiconductor module 100 described in FIG. 1 and FIG. 2. The control external connection pin 41 in the present example is electrically connected to the control terminal 22 of each semiconductor chip 20.

As described above, the control internal connection pin 31 having a high resistance is connected to the control terminal 22 of each semiconductor chip 20. Each control internal connection pin 31 is electrically connected to the control external connection pin 41 via the internal wiring of the semiconductor module 100. An inductor 21 shows an inductance component of the internal wiring. By providing the control internal connection pin 31 having a high electrical resistance to each of the semiconductor chips 20 connected in parallel, electrical oscillations between the semiconductor chips 20 can be suppressed.

As described above, in the semiconductor device 300, an additional resistor may not be provided to the wiring substrate 18 and the like. Consequently, even in a case where a number of semiconductor chips 20 are provided, a resistance component can be easily connected to the control terminal 22 of each semiconductor chip 20.

Also, the electrical resistance values of the control internal connection pins 31 connected to the respective semiconductor chips 20 are the same. In another example, in a case where the electrical characteristics of the respective semiconductor chips 20 are desired to be individually adjusted, the electrical resistance values of the respective control internal connection pins 31 may be made different.

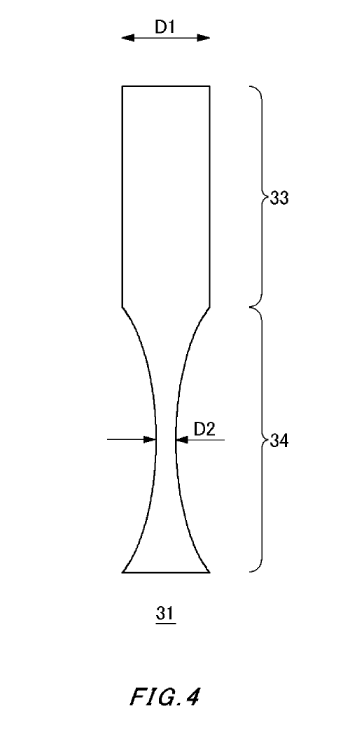

FIG. 4 is a side view showing an exemplary shape of the control internal connection pin 31. The control internal connection pin 31 of the present example has a portion a diameter of which is smaller than that of the main internal connection pin 32. In the example shown in FIG. 4, the control internal connection pin 31 has a first portion 33 and a second portion 34. The smallest diameter D2 of the second portion 34 is smaller than the smallest diameter of the main internal connection pin 32. The diameter of the connection pin refers to a diameter in a plane perpendicular to the direction in which current flows.

The second portion 34 may have a shape, whose diameter decreases as the distance increases from the connecting section with the first portion 33 and diameter increases as the distance further increases from a predetermined distance away from the connecting section. The diameter of the second portion 34 may vary continuously as shown in FIG. 4, or may vary in a stepwise manner. The diameter of an end of the second portion 34, the end opposite to the first portion 33, may be the same as the diameter D1 of the first portion 33. The end of the second portion 34 may be soldered to the control terminal 22 of the semiconductor chip 20.

The first portion 33 may have a columnar shape having a substantially constant diameter D1. The first portion 33 may be arranged to penetrate the wiring substrate 18. The first portion 33 may be soldered to the wiring substrate 18. The first portion 33 may be provided with a protruding portion that prevents the first portion 33 from falling off from the wiring substrate 18. The diameter D1 may be the same as the diameter of the main internal connection pin 32.

When the first portion 33 has substantially the constant diameter D1, the wiring substrate 18 and the first portion 33 can be connected regardless of the depth of insertion of the first portion 33 into the wiring substrate 18. Also, the electrical resistance of the control internal connection pin 31 can be increased by providing the second portion 34 having a small diameter. Also, the connection reliability between the control terminal 22 and the control internal connection pin 31 can be maintained by increasing the diameter of the lower end of the second portion 34.

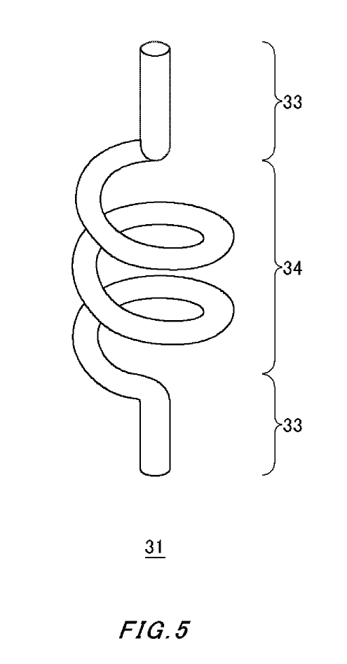

FIG. 5 is a perspective view showing another exemplary shape of the control internal connection pin 31. The control internal connection pin 31 of the present example has a current path longer than that of the main internal connection pin 32. The height of the control internal connection pin 31 in the direction perpendicular to the upper surface of the semiconductor chip 20 may be the same as the height of the main internal connection pin 32.

The control internal connection pin 31 of the present example has the first portion 33 and the second portion 34. The shape of the first portion 33 may be the same as the shape of a portion of the main internal connection pin 32. The shape of the second portion 34 may be different from the shape of any portion of the main internal connection pin 32. For example, the main internal connection pin 32 may be a pin having a columnar shape, and the second portion 34 may have a spiral shape. The diameter of the conductor of the second portion 34 may be the same as or smaller than the diameter of the conductor of the first portion 33. The shape of the second portion 34 only needs to be a shape by which the length of the current path is increased more than by a linear shape. It may have a zigzag polygonal line shape or a shape of reverse curves that are alternatingly arranged. It may be another shape.

Such shapes make it possible to increase the electrical resistance of the control internal connection pin 31. Note that the material of the control internal connection pin 31 shown in FIG. 4 and FIG. 5 may be the same as the material of the main internal connection pin 32. It may be material having an electrical resistivity higher than that of the material of the main internal connection pin 32.

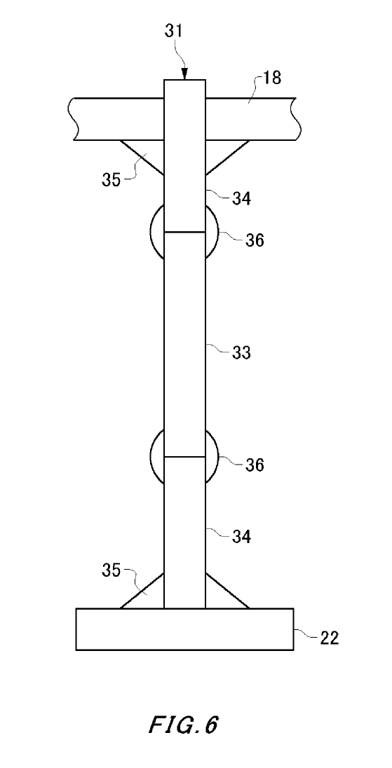

FIG. 6 is a cross-sectional view showing another exemplary shape of the control internal connection pin 31. The control internal connection pin 31 of the present example has the first portion 33 and the second portions 34. The first portion 33 and the second portions 34 may have a columnar shape.

The second portions 34 are connected to the ends of the first portion 33. Although the second portions 34 are connected to both ends of the first portion 33 in the present example, the second portion 34 may be connected only to the end of the first portion 33, the end on the side of the wiring substrate 18. The second portion 34 may be connected only to the end of the first portion 33, the end on the side of the control terminal 22. The first portion 33 and the second portion 34 may have the same diameter.

The second portion 34 is formed of material having an electrical resistivity higher than that of the material of the first portion 33. For example, the material of the first portion 33 is copper, and the material of the second portion 34 is titanium or tungsten. The material of the first portion 33 may also be the same as the material of the main internal connection pin 32.

The end of the second portion 34 on the side of the control terminal 22 is connected to the control terminal 22 by a solder portion 35. The second portion 34 on the side of the wiring substrate 18 is connected to the wiring substrate 18 by the solder portion 35. The difference between the thermal expansion coefficient of the material of the second portion 34 and that of the material of the solder portion 35 is preferably smaller than the difference between the thermal expansion coefficient of the material of the first portion 33 and that of the material of the solder portion 35. The generation of cracks or the like in the solder portion 35 can be thereby suppressed, and this can improve the connection reliability of the control internal connection pin 31 with respect to the solder portion 35.

The first portion 33 and the second portions 34 are connected by the connection portions 36. The connection portion 36 is solder, for example. The connection portion 36 may be solder formed of the same material as that of the solder portion 35. In another example, the connection portion 36 may be adhesive material or the like.

The structure of the control internal connection pin 31 shown in FIG. 6 and the shape of the control internal connection pin 31 shown in FIG. 4 or FIG. 5 may be combined. For example, the first portion 33 in FIG. 6 may also have a shape similar to that of the control internal connection pin 31 shown in FIG. 4 or FIG. 5.

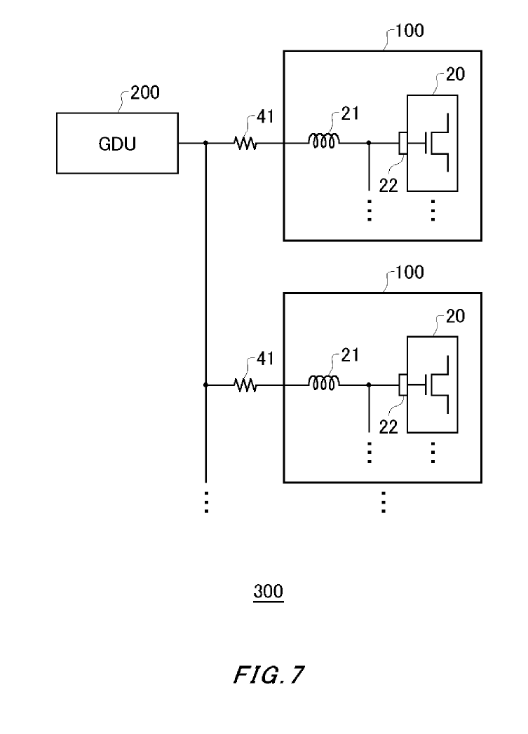

FIG. 7 is a diagram showing another exemplary semiconductor device 300. In the semiconductor device 300 of the present example, the electrical resistance of the control external connection pin 41 may be higher than the electrical resistance of the main external connection pin 42. At least part of each external connection pin is exposed to the outside of the package portion 10. In the example shown in FIG. 7, a plurality of semiconductor chips 20 are connected in parallel to one control external connection pin 41.

The electrical resistance of the control external connection pin 41 may be increased in a manner similar to the case of the control internal connection pin 31. For example, the control external connection pin 41 can be formed of material having an electrical resistivity higher than that of the main external connection pin 42. Also, the control external connection pin 41 may have a structure and a shape that are similar to those of the control internal connection pin 31 shown in FIG. 3 to FIG. 6. Note that the size of the control external connection pin 41 may be greater than that of the control internal connection pin 31.

By increasing the electrical resistance of the control external connection pin 41, the gate resistance of the semiconductor chip 20 can be set to a predetermined resistance value without adding an external resistor to the semiconductor chip 20 in each semiconductor module 100. This can reduce the complexity of the wiring pattern in the wiring substrate 18 and also reduce the component cost. Although FIG. 7 shows an example in which a plurality of semiconductor modules 100 are provided in parallel, the semiconductor device 300 may have one semiconductor module 100 similarly to the example shown in FIG. 3.

Moreover, by increasing the electrical resistance of the control external connection pin 41, an output resistance of the gate driver unit 200 can be lowered or omitted. This can reduce heat generation in the output resistance of the gate driver unit 200, so that the power saving of the gate driver unit 200 can be achieved, and the heat-releasing means can be miniaturized.

As shown in FIG. 7, in a case where package portions 10 of a plurality of semiconductor modules 100 are provided in parallel, the electrical resistance of the control external connection pin 41 of each semiconductor module 100 is preferably high. This can suppress electrical oscillations between the semiconductor modules 100. Although the control internal connection pin 31 of each semiconductor module 100 is not shown in the example of FIG. 7, the control internal connection pin 31 may have the electrical resistance equivalent to that of the main internal connection pin 32. It may also have an electrical resistance higher than that of the main internal connection pin 32.

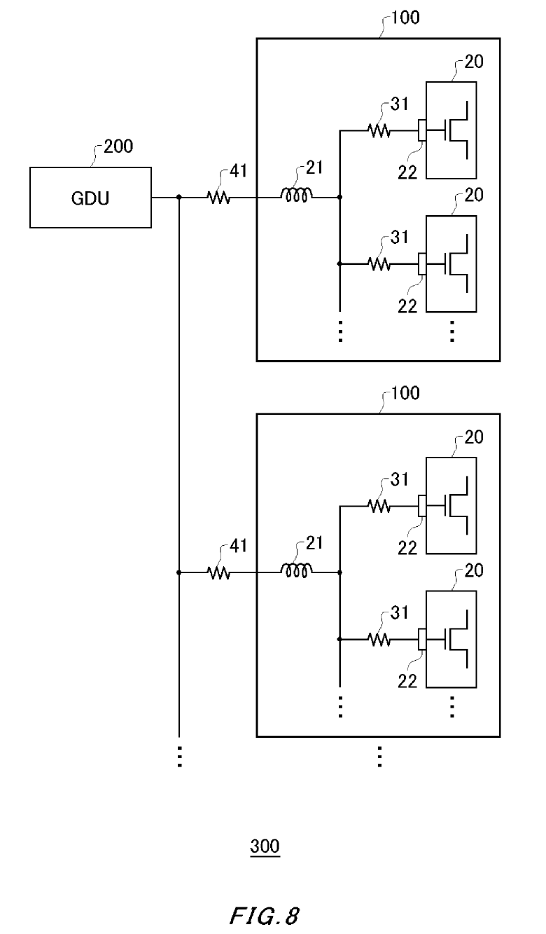

FIG. 8 is a diagram showing another exemplary semiconductor device 300. In the present example, the electrical resistance of the control external connection pin 41 is higher than the electrical resistance of the main external connection pin 42. Also, the electrical resistance of the control internal connection pin 31 is higher than the electrical resistance of the main internal connection pin 32.

Such a configuration can increase degrees of freedom in setting of the resistance component connected to the control terminal 22 of the semiconductor chip 20. For example, even in a case where the electrical resistance of the control internal connection pin 31 cannot be sufficiently increased, the overall resistance components can be adjusted by increasing the electrical resistance of the control external connection pin 41.

The electrical resistance per control internal connection pin 31 may be higher than the electrical resistance per control external connection pin 41. The plurality of control internal connection pins 31 in one semiconductor module 100 are connected in parallel. Accordingly, the electrical resistance of the control internal connection pin 31 is preferably increased such that the combined resistance of the plurality of control internal connection pins 31 as observed from the outside of the semiconductor module 100 does not become too small.

The shape of the control internal connection pin 31 and the shape of the control external connection pin 41 may be similar or non-similar. The control external connection pin 41 is longer than the control internal connection pin 31 and has room in the surrounding space in many cases. Accordingly, the electrical resistance of the control external connection pin 41 can be increased by making the shape thereof non-linear as in the example shown in FIG. 5 and the like. The control external connection pin 41 may have a portion the current path of which is curved. In contrast, the control internal connection pin 31 may have a columnar shape the current path of which is linear.

The material of the control internal connection pin 31 and the material of the control external connection pin 41 may be the same or different. As described above, because the electrical resistance of the control external connection pin 41 can be easily increased by devising the shape thereof, the control external connection pin 41 may be formed of material having an electrical resistivity lower than that of the control internal connection pin 31. The control external connection pin 41 may be formed of the same material as that of at least one of the main external connection pin 42 and the main internal connection pin 32.

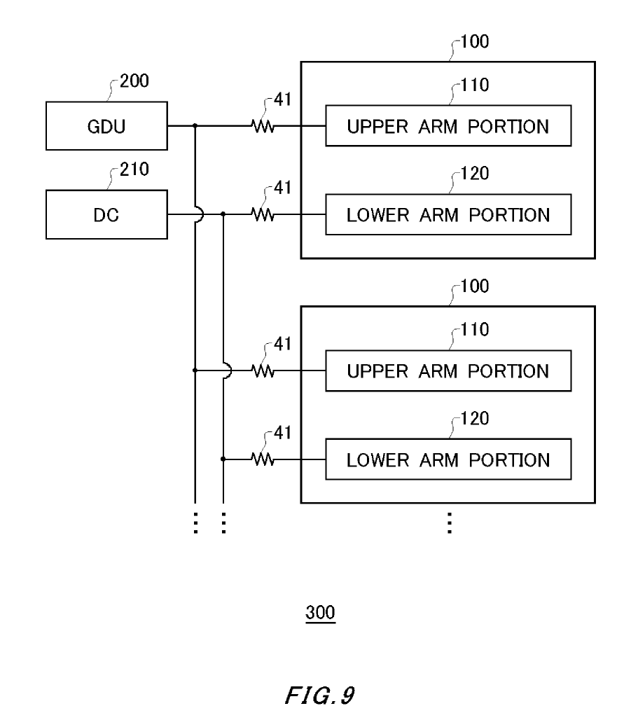

FIG. 9 is a diagram showing another exemplary semiconductor device 300. The semiconductor device 300 of the present example includes a plurality of semiconductor modules 100 provided in parallel. In each semiconductor module 100, an upper arm portion 110 and a lower arm portion 120 of an inverter circuit are accommodated. For example, each arm portion includes a switching element such as an IGBT and a freewheeling diode connected between two main terminals of the switching element (between an emitter terminal and a collector terminal, for example).

Each arm portion has one or more semiconductor chips 20. Each semiconductor module 100 has the control external connection pins 41 with respect to the upper arm portion 110 and the lower arm portion 120, the control external connection pins 41 having a high resistance. For example, each control external connection pin 41 with respect to the upper arm portion 110 is connected to the gate driver unit 200. Also, each control external connection pin 41 with respect to the lower arm portion 120 is connected to a DC power source 210. The DC power source 210 outputs a predetermined constant voltage.

Such a configuration can suppress electrical oscillations between the semiconductor modules 100 each having the upper arm portion 110 and the lower arm portion 120. The control external connection pin 41 connected to the upper arm portion 110 and the control external connection pin 41 connected to the lower arm portion 120 may have the same shape and be formed of the same material. Also, in the semiconductor device 300 of the present example, similarly to the example shown in FIG. 8, the control internal connection pin 31 having a high resistance may be provided inside each semiconductor chip 20.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

What is claimed is:

1. A semiconductor device comprising:
a semiconductor chip having a main terminal and a control terminal;
a main connection pin electrically connected to the main terminal; and
a control connection pin electrically connected to the control terminal and having an electrical resistance higher than that of the main connection pin.

2. The semiconductor device according to claim 1, wherein the control connection pin includes material having an electrical resistivity higher than that of material of the main connection pin.

3. The semiconductor device according to claim 2, wherein the control connection pin includes at least one of tungsten and titanium.

4. The semiconductor device according to claim 1, wherein the control connection pin has a portion a diameter of which is smaller than a diameter of the main connection pin.

5. The semiconductor device according to claim 1, wherein the control connection pin has a current path longer than that of the main connection pin.

6. The semiconductor device according to claim 1, wherein the control connection pin has a first portion and a second portion that is connected to an end of the first portion and formed of material having an electrical resistivity higher than that of material of the first portion.

7. The semiconductor device according to claim 6, wherein the first portion is formed of copper, and the second portion includes at least one of tungsten and titanium.

8. The semiconductor device according to claim 1, further comprising:
a package portion that accommodates the semiconductor chip; and
a wiring substrate that is accommodated in the package portion and arranged to face the semiconductor chip,
wherein the control connection pin is a control internal connection pin that electrically connects, inside the package portion, the control terminal of the semiconductor chip and the wiring substrate.

9. The semiconductor device according to claim 8, comprising a plurality of the semiconductor chips in parallel,
wherein the control internal connection pin is provided to each semiconductor chip.

10. The semiconductor device according to claim 1, further comprising a package portion that accommodates the semiconductor chip,
wherein the control connection pin is a control external connection pin at least part of which is exposed to outside of the package portion.

11. The semiconductor device according to claim 10, comprising a plurality of the semiconductor chips in parallel,
wherein two or more of the semiconductor chips are electrically connected to the one control external connection pin.

12. The semiconductor device according to claim 10, comprising a plurality of the package portions in parallel,
wherein the control external connection pin is provided in each of the package portions.

13. The semiconductor device according to claim 10, further comprising:
a wiring substrate accommodated in the package portion and arranged to face the semiconductor chip;
a main internal connection pin that electrically connects, inside the package portion, the main terminal of the semiconductor chip and the wiring substrate; and
a control internal connection pin that electrically connects, inside the package portion, the control terminal of the semiconductor chip and the wiring substrate and that has an electrical resistance higher than that of the main internal connection pin.

14. The semiconductor device according to claim 13, wherein the control internal connection pin has an electrical resistance higher than that of the control external connection pin.
